(19) United States
(12) Patent Application Publication
(10) Pub. No.: US 2026/0101695 A1
(43) Pub. Date: Apr. 9, 2026

(54) THERMOCOMPRESSION BONDING HEAD FIXTURE

(71) Applicant: International Business Machines Corporation, Armonk, NY (US)

(72) Inventors: Prabudhya Roy Chowdhury, Albany, NY (US); Aakrati Jain, Albany, NY (US); Sathyanarayanan Raghavan, Ballston Lake, NY (US); Mukta Ghate Farooq, HOPEWELL JCT, NY (US)

(21) Appl. No.: 18/896,826

(22) Filed: Sep. 25, 2024

(51) Int. Cl. H01L 23/00; H01L 21/67

(52) U.S. Cl. CPC H10P 72/0402; H10W 72/07141; H10W 72/07168; H10W 80/102; H10W 80/334

(57) ABSTRACT

Thermocompression bonding head fixture designs and techniques for use thereof are provided. In one aspect, an exemplary bonding head fixture includes: a workpiece contact surface; at least one recess in the workpiece contact surface; and heat passages leading into and out of the at least one recess. In another aspect, an exemplary bonding head includes: a bonding head fixture having a workpiece contact surface, at least one recess in the workpiece contact surface, and heat passages leading into and out of the at least one recess; and a heat source connected to at least one of the heat passages. Methods for use of the present bonding head fixtures are also provided.

### BACKGROUND

The present invention relates generally to the electrical, electronic and computer arts and, more particularly, to thermocompression bonding head fixture designs and techniques for use thereof.

Thermocompression bonding is widely used in semiconductor device assembly. With thermocompression bonding, objects such as semiconductor chips are brought into contact with one another, and both force and heat are applied simultaneously to bond the objects together.

In practice, during manufacture a bonding tool is used to perform thermocompression bonding. Typically, such a bonding tool has a ‘pickup collet’ or simply ‘collet’ that serves to attach an object such as a semiconductor chip to the bonding tool and hold it in place. A heat source then heats the object, while the bonding tool applies pressure to both the object and its bonding target (also referred to herein as ‘workpieces’). By way of example only, the object and its bonding target may be two semiconductor chips that are joined via thermocompression bonding.

However, non-uniformity in the heat profile of conventional bonding tools causes variation in the heat applied across the object during bonding. As a result, there can be an undesirable variation in the bonding conditions across the workpieces.

### BRIEF SUMMARY

Principles of the invention provide thermocompression bonding head fixture designs and techniques for use thereof.

In one aspect, an exemplary bonding head fixture includes: a workpiece contact surface; at least one recess in the workpiece contact surface; and heat passages leading into and out of the at least one recess.

In another aspect, an exemplary bonding head includes: a bonding head fixture having a workpiece contact surface, at least one recess in the workpiece contact surface, and heat passages leading into and out of the at least one recess; and a heat source connected to at least one of the heat passages.

In yet another aspect, an exemplary method includes: gripping a workpiece with a bonding head fixture, the bonding head fixture having a workpiece contact surface, at least one recess in the workpiece contact surface, and heat passages leading into and out of the at least one recess, where the workpiece contact surface directly contacts the workpiece; and heating the workpiece by direct heating at the workpiece contact surface, and by providing a heated fluid to the at least one recess via the heat passages.

As used herein, “facilitating” an action includes performing the action, making the action easier, helping to carry the action out, or causing the action to be performed. Thus, by way of example and not limitation, instructions executing on one processor might facilitate an action carried out by semiconductor processing equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
Thermocompression bonding head fixture designs that effectively provide uniform heating across a workpiece;
Where the present thermocompression bonding head fixture designs provide recesses at a workpiece contact surface in order to create heating uniformity by redistributing heat;
Where the recesses at the workpiece contact surface can be separate from vacuum channels used to grip the workpiece; and
Where the present thermocompression bonding head fixture designs can accommodate a variety of different workpiece configurations including, but not limited to, flexible substrates such as thin films.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a three-dimensional diagram illustrating an exemplary bonding head fixture according to one or more embodiments of the present invention;

FIG. 2 is a top-down diagram and FIG. 3 is a cross-sectional diagram illustrating another exemplary bonding head fixture according to one or more embodiments of the present invention;

FIG. 4 is a top-down diagram and FIG. 5 is a cross-sectional diagram illustrating yet another exemplary bonding head fixture according to one or more embodiments of the present invention;

FIG. 6 is a cross-sectional diagram illustrating a bonding head having the present bonding head fixture affixed to a bonding head unit according to one or more embodiments of the present invention;

FIG. 7 is a cross-sectional diagram illustrating an example of the present bonding head being used to process a workpiece according to one or more embodiments of the present invention;

FIG. 8 is a three-dimensional diagram illustrating an exemplary bonding head fixture having multiple recesses according to one or more embodiments of the present invention; and

FIG. 9 is a three-dimensional diagram illustrating an exemplary bonding head fixture having fluid flow inlets over a recess and fluid flow outlets located at an outer edge thereof according to one or more embodiments of the present invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As highlighted above, conventional bonding heads can exhibit non-uniform heating, which can undesirably lead to variations in the bonding conditions across a workpiece. Namely, as is the case with many conventional bonding head designs, heating all areas of the bonding head uniformly typically results in a center of the bonding head being the highest in temperature due to thermal crowding, and the corners being the lowest in temperature. Thermal crowding refers to temperature elevations associated with the close proximity of objects in a confined space.

However, as will be described in detail below, the present bonding head fixture designs employ a recess(es) in a workpiece contact surface that redistribute heat across the fixture in order to achieve heating uniformity. Notably, as its name implies, the workpiece contact surface of the fixture makes physical and thermal contact with a given workpiece. However, where the recess(es) are present, there is no direct physical/thermal contact between the fixture and the workpiece. Thus, the positioning of these recess(es) is configured to not allow heat to pass directly through the fixture to the workpiece in certain areas (such as at the center of the fixture) while, at the same time, allowing heat to pass directly through the fixture to the workpiece in other areas (such as at the corners of the fixture). Doing so intentionally creates a secondary temperature non-uniformity to counter the initial center-to-corner variation described above.

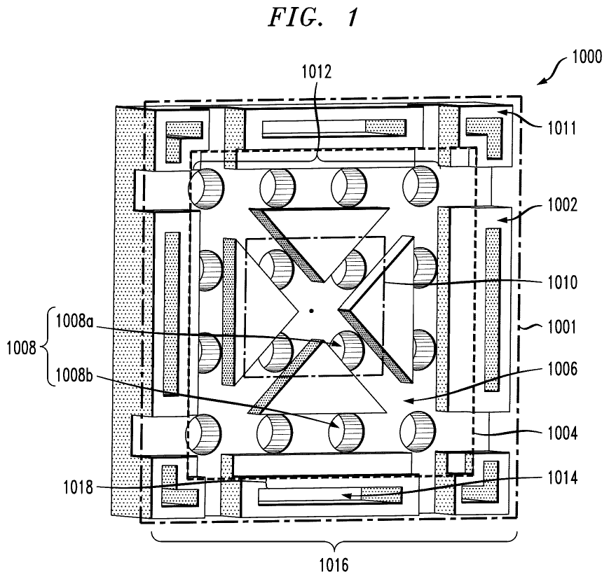

For instance, referring to FIG. 1, an exemplary bonding head fixture 1000 in accordance with the present techniques is shown. Bonding head fixture 1000 has a workpiece contact surface 1002. As its name implies, the workpiece contact surface 1002 is a part of the bonding head fixture 1000 that makes both direct physical and direct thermal contact with a given workpiece 1001 (the outline of which is shown with patterned dashes) when the bonding head fixture 1000 is in use (see also below).

As highlighted above and as shown in FIG. 1, there however is a recess 1004 present in the workpiece contact surface 1002. Notably, where the recess 1004 is present in the workpiece contact surface 1002 the bonding head fixture 1000 does not make direct physical and direct thermal contact with the workpiece. Namely, since surfaces of the bonding head fixture 1000 within the recess 1004 are offset in from the workpiece contact surface 1002, they will not make direct physical/thermal contact with the workpiece. See, for example, surface 1006 of the bonding head fixture 1000 within the recess 1004 which is set in from the workpiece contact surface 1002.

Heat passages 1008 are present in the bonding head fixture 1000 leading into and out of the recess 1004. According to an exemplary embodiment, the heat passages 1008 include both fluid flow inlets 1008a and fluid flow outlets 1008b. As will be described in detail below, the fluid flow inlets 1008a are connected to a heat source (not shown), and the fluid flow inlets 1008a and the fluid flow outlets 1008b will serve to direct a heated fluid into and out of the recess 1004, respectively. The fluid can be a gas or a liquid. For instance, according to one exemplary embodiment, the fluid that is heated is a gas such as, but not limited to, air and/or an inert gas such as nitrogen. Use of an inert gas as the heated fluid preferably avoids oxidation. The inlet fluid is distributed via the fluid flow inlets 1008a evenly across the surface to ensure that the workpiece is heated uniformly. As highlighted above, the recess 1004 serves to redistribute heat across the bonding head fixture 1000 in order to achieve heating uniformity. Namely, since there is no direct physical/thermal contact between the bonding head fixture 1000 and the workpiece within the recess 1004, heat will not be allowed to pass directly through the bonding head fixture 1000 to the workpiece where the recess 1004 is present (such as at a center 1010 of the bonding head fixture 1000). At the same time, other areas of the bonding head fixture 1000 such as the workpiece contact surface 1002 at corners 1011 of the bonding head fixture 1000 directly contact the workpiece, allowing heat to pass directly through the bonding head fixture 1000 to the workpiece. This intentionally creates a secondary temperature non-uniformity to counter the initial center-to-corner variation described above.

In the exemplary configuration depicted in FIG. 1, the fluid flow inlets 1008a are located at the center 1010 of the bonding head fixture 1000, and the fluid flow outlets 1008b are located along inner edges 1012 of the bonding head fixture 1000. By ‘inner’ it is meant simply that the inner edges 1012 are the edges of the bonding head fixture 1000 located inward of vacuum channels 1014, whereas the vacuum channels 1014 are located in the workpiece contact surface 1002 along an outer edge 1016 of the bonding head fixture 1000.

As will be described in detail below, the vacuum channels 1014 are connected to a vacuum source (not shown) and will serve to grip and hold onto the workpiece 1001. Notably, in the instant example, the vacuum channels 1014 are separate from (i.e., not connected to) the recess 1004. Namely, a portion of the workpiece contact surface 1002 (see, e.g., portion 1018 of the workpiece contact surface 1002) separates each of the vacuum channels 1014 from the recess 1004.

In one exemplary embodiment, the bonding head fixture 1000 is formed from a rigid material such as a metal like aluminum and/or copper. Standard machining process can be employed to pattern the above-described features such as the recess 1004, the heat passages 1008 (i.e., the fluid flow inlets 1008a and the fluid flow outlets 1008b), the vacuum channels 1014, etc. in the bonding head fixture 1000.

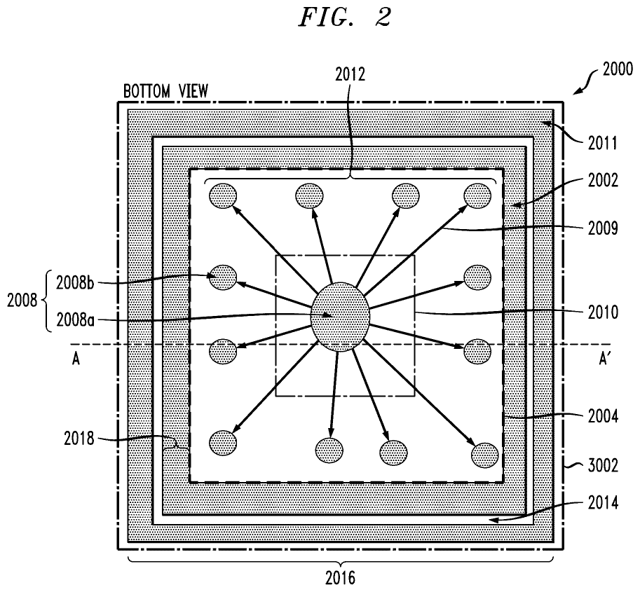

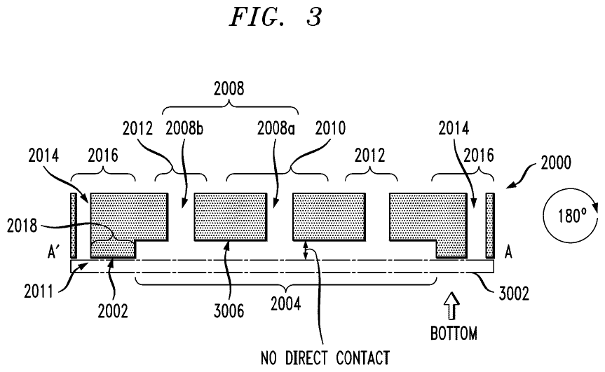

Another exemplary bonding head fixture 2000 in accordance with the present techniques is shown in FIG. 2 and FIG. 3. In order to illustrate unique elements of the present bond head fixture design at an interface with a workpiece, FIG. 2 provides a top-down view of a bottom of the bonding head fixture 2000. FIG. 3 illustrates a cross-sectional view of the bonding head fixture 2000 taken along line A-A′. However, the view in FIG. 3 is rotated 180 degrees (°) relative to that of FIG. 2 in order to orient the bottom of the bonding head fixture 2000 and its associated elements such as a workpiece contact surface 2002 to be downward facing, as they would generally be during use.

As shown in FIG. 2, similar to the previous example bonding head fixture 2000 has a workpiece contact surface 2002 that will make both direct physical and direct thermal contact with a given workpiece 3002 (the outline of which is shown with patterned dashes) when the bonding head fixture 2000 is in use (see FIG. 3 below), and a recess 2004 present in the workpiece contact surface 2002. Notably, where the recess 2004 is present in the workpiece contact surface 2002, the bonding head fixture 2000 does not make direct physical and direct thermal contact with the workpiece 3002. Namely, referring briefly to FIG. 3, since surfaces of the bonding head fixture 2000 within the recess 2004 are offset in from the workpiece contact surface 2002, they will not make direct physical/thermal contact with the workpiece 3002. See, for example, surface 3006 of the bonding head fixture 2000 within the recess 2004 which is set in from the workpiece contact surface 2002.

Heat passages 2008 are present in the bonding head fixture 2000 leading into and out of the recess 2004. In this example, however, the heat passages 2008 include a single fluid flow inlet 2008a and multiple fluid flow outlets 2008b. As will be described in detail below, the fluid flow inlet 2008a is connected to a heat source (not shown), and the fluid flow inlet 2008a and the fluid flow outlets 2008b will serve to direct a heated fluid (e.g., a gas or a liquid) into and out of the recess 2004, respectively. See, e.g., arrows 2009.

In the same manner as described above, the recess 2004 serves to redistribute heat across the bonding head fixture 2000 in order to achieve heating uniformity. Namely, since there is no direct physical/thermal contact between the bonding head fixture 2000 and the workpiece 3002 within the recess 2004, heat will not be allowed to pass directly through the bonding head fixture 2000 to the workpiece 3002 where the recess 2004 is present (such as at a center 2010 of the bonding head fixture 2000). At the same time, other areas of the bonding head fixture 2000 such as the workpiece contact surface 2002 at corners 2011 of the bonding head fixture 2000 directly contact the workpiece 3002, allowing heat to pass directly through the bonding head fixture 2000 to the workpiece 3002. This intentionally creates a secondary temperature non-uniformity to counter the initial center-to-corner variation described above. In the exemplary configuration depicted in FIG. 2, the fluid flow inlet 2008a is located at the center 2010 of the bonding head fixture 2000, and the fluid flow outlets 2008b are located along inner edges 2012 of the bonding head fixture 2000 (i.e., the inner edges 2012 are located inward of a vacuum channel 2014).

As in the preceding example, the vacuum channel 2014 is located in the workpiece contact surface 2002 along an outer edge 2016 of the bonding head fixture 2000. This vacuum channel 2014 is connected to a vacuum source (not shown) and will serve to grip the workpiece 3002. Here as well, the vacuum channel 2014 is separate from (i.e., not connected to) the recess 2004. Namely, a portion of the workpiece contact surface 2002 (see, e.g., portion 2018 of the workpiece contact surface 2002) separates the vacuum channel 2014 from the recess 2004.

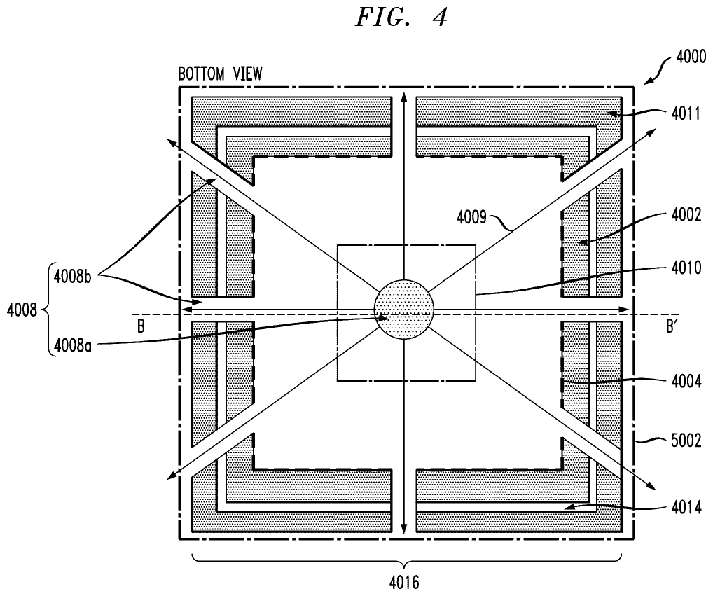

Bonding head fixture designs are also contemplated herein where the fluid flow outlets are instead located at the outer edge of the bonding head fixture in order to enhance lateral hot fluid flow. See, for instance, exemplary bonding head fixture 4000 shown in FIG. 4 and FIG. 5. Again, in order to illustrate unique elements of this bond head fixture design at an interface with a workpiece, FIG. 4 provides a top-down view of a bottom of the bonding head fixture 4000. FIG. 5 illustrates a cross-sectional view of the bonding head fixture 4000 taken along line B-B′. However, the view in FIG. 5 is rotated 180° relative to that of FIG. 4 in order to orient the bottom of the bonding head fixture 4000 and its associated elements such as a workpiece contact surface 4002 to be downward facing, as they would generally be during use.

Similar to the previous examples, bonding head fixture 4000 has a workpiece contact surface 4002 that will make both direct physical and direct thermal contact with a given workpiece 5002 (the outline of which is shown with patterned dashes) when the bonding head fixture 4000 is in use (see FIG. 5 below), and a recess 4004 present in the workpiece contact surface 4002. Where the recess 4004 is present in the workpiece contact surface 4002, the bonding head fixture 4000 does not make direct physical and direct thermal contact with the workpiece 5002. Namely, referring briefly to FIG. 5, since surfaces of the bonding head fixture 4000 within the recess 4004 are offset in from the workpiece contact surface 4002, they will not make direct physical/thermal contact with the workpiece 5002. See, for example, surface 5006 of the bonding head fixture 4000 within the recess 4004 which is set in from the workpiece contact surface 4002.

Heat passages 4008 are present in the bonding head fixture 4000 leading into and out of the recess 4004. The heat passages 4008 include a single fluid flow inlet 4008a and multiple fluid flow outlets 4008b. As will be described in detail below, the fluid flow inlet 4008a is connected to a heat source (not shown), and the fluid flow inlet 4008a and the fluid flow outlets 4008b will serve to direct a heated fluid (e.g., a gas or a liquid) into and out of the recess 4004, respectively. See, e.g., arrows 4009. Here, the fluid flow inlet 4008a is also located at a center 4010 of the bonding head fixture 4000. In this example, however, the fluid flow outlets 4008b are located at an outer edge 4016 of the bonding head fixture 4000 in order to enhance lateral hot fluid flow. For instance, in the example depicted in FIG. 4 and FIG. 5, the fluid flow outlets 4008b run perpendicular to a vacuum channel 4014 and, accordingly, pass through the vacuum channel 4014. In that case, a vacuum will be drawn all over the bonding head fixture 4000, including within the recess 4004, since the fluid flow outlets 4008b connect the recess 4004 to the vacuum channel 4014.

Nonetheless, in the same manner as described above, the recess 4004 serves to redistribute heat across the bonding head fixture 4000 in order to achieve heating uniformity. Namely, since there is no direct physical/thermal contact between the bonding head fixture 4000 and the workpiece 5002 within the recess 4004, heat will not be allowed to pass directly through the bonding head fixture 4000 to the workpiece 5002 where the recess 4004 is present (such as at the center 4010 of the bonding head fixture 4000). At the same time, other areas of the bonding head fixture 4000 such as the workpiece contact surface 4002 at corners 4011 of the bonding head fixture 4000 directly contact the workpiece 5002, allowing heat to pass directly through the bonding head fixture 4000 to the workpiece 5002.

As in the preceding examples, the vacuum channel 4014 is located in the workpiece contact surface 4002 along the outer edge 4016 of the bonding head fixture 4000. This vacuum channel 4014 is connected to a vacuum source (not shown) and will serve to grip and hold onto the workpiece 5002. By contrast, however, the fluid flow outlets 4008b pass through the vacuum channel 4014. Accordingly, the vacuum source will draw a vacuum all over the bonding head fixture 4000, including within the recess 4004, since the fluid flow outlets 4008b connect the recess 4004 to the vacuum channel 4014.

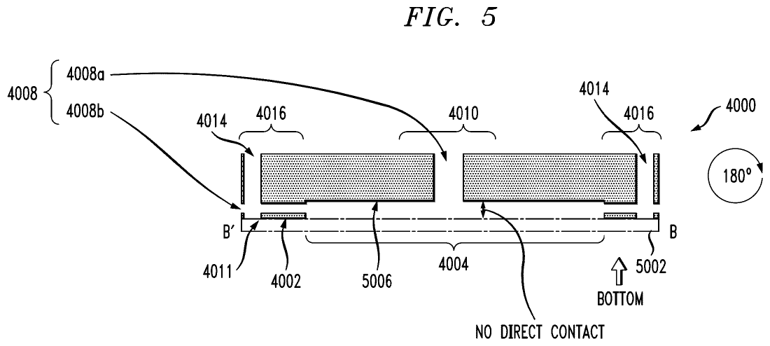

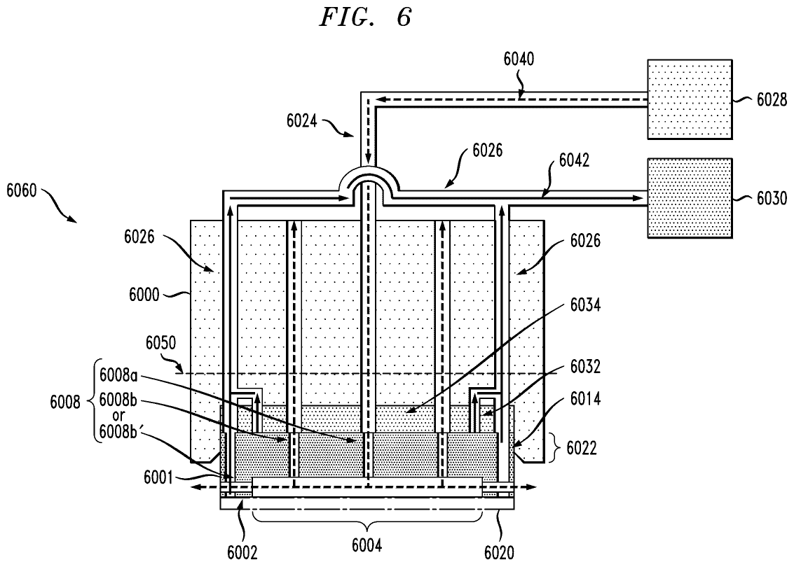

As highlighted above, the present bonding head fixtures can be affixed to a bonding head unit that provides both heat and vacuum source attachments. See, for example, bonding head 6060 in FIG. 6 having a bonding head fixture 6001 affixed to a bottom of a bonding head unit 6000. The bonding head fixture 6001 is generally representative of any of the bonding head fixtures provided herein, i.e., bonding head fixture 1000, 2000, 4000, 8000, 9000, etc. As such, in the same manner, the bonding head fixture 6001 includes a workpiece contact surface 6002 that makes both direct physical and direct thermal contact with a given workpiece 6020, a recess 6004 present in the workpiece contact surface 6002, heat passages 6008 leading into and out of the recess 6004, and a vacuum channel 6014. As above, the heat passages 6008 contain a fluid flow inlet 6008a and fluid flow outlets 6008b or 6008b′. Namely, as per the preceding examples, the fluid flow outlets 6008b or 6008b′ can be located along inner or outer edges of the bonding head fixture 6001, respectively. Similarly, the vacuum channel 6014 is located along the outer edge of the bonding head fixture 6001.

Optionally, the bonding head unit 6000 can have flanges 6022 on the bottom thereof configured to properly align the bonding head fixture 6001 with the bonding head unit 6000. Any suitable means for affixing the bonding head fixture 6001 to the bonding head unit 6000 may be employed including, but not limited to, adhesives and/or mechanical fasteners. Alternatively, as shown in FIG. 6, the bonding head unit 6000 can employ a vacuum configured to hold the bonding head fixture 6001 to the bonding head unit 6000.

The bonding head unit 6000 contains passages 6024 and 6026 connecting a fluid source 6028 and a vacuum source 6030 to the fluid flow inlet 6008a and the vacuum channel 6014 of the bonding head fixture 6001, respectively. Optionally, portions 6032 of the passages 6026 can be present leading to an interface between the bonding head fixture 6001 and the bonding head unit 6000 thereby providing the vacuum used to hold the bonding head fixture 6001 to the bonding head unit 6000.

According to an exemplary embodiment, a heater 6034 is present at a junction between the bonding head unit 6000 and the bonding head fixture 6001, such that the heater 6034 has direct physical/thermal contact with the bonding head fixture 6001 when the bonding head fixture 6001 is affixed to the bonding head unit 6000. Heater 6034 can be a resistive heating element and/or any other suitable type of heating element known in the art. As shown in FIG. 6, passage 6024 passes through the heater 6034. Thus, according to an exemplary embodiment, heater 6034 serves to i) directly heat the bonding head fixture 6001 and ii) heat the fluid (e.g., a gas or a liquid) from the fluid source 6028 as it is passed through the passage 6024 in the heater 6034 to generate the heated fluid. As such, the passage 6024 ultimately provides heated fluid to the heat passages 6008 (namely fluid flow inlet 6008a) and recess 6004. In that manner, the fluid source 6028 and the heater 6034 may also be referred to collectively herein as a source of ‘heated fluid’ or simply a ‘heat source’.

Dashed arrows 6040 are used to represent a path of the fluid flow from the fluid source 6028, through the bonding head fixture 6001 and the bonding head unit 6000. Notably, the heated fluid enters the recess 6004 in the bonding head fixture 6001 via the fluid flow inlet 6008a, and exits the recess 6004 in the bonding head fixture 6001 via the fluid flow outlets 6008b or 6008b′, depending on which configuration is employed (see above). Solid arrows 6042 are used to represent a vacuum path from the vacuum source 6030, through the bonding head fixture 6001 and the bonding head unit 6000. Notably, a vacuum is drawn at the workpiece contact surface 6002 via the vacuum channel 6014 to grip/hold onto the workpiece 6020. As described above, optionally, a vacuum can be drawn at the interface between the bonding head fixture 6001 and the bonding head unit 6000 to hold the bonding head fixture 6001 to the bonding head unit 6000.

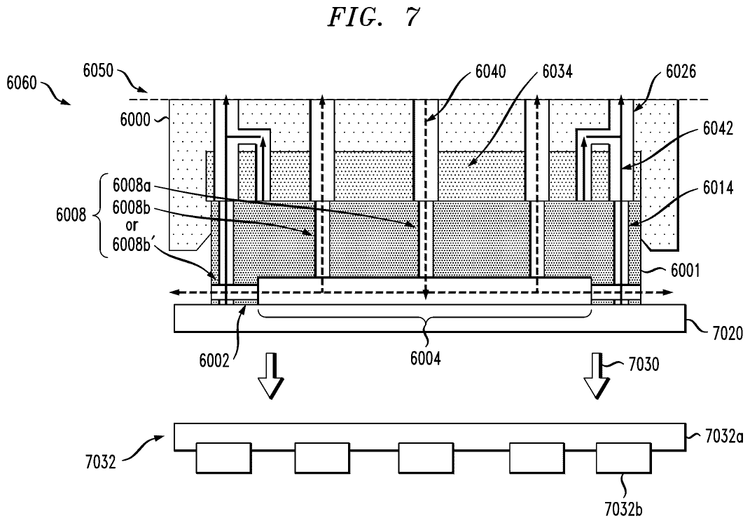

A non-limiting example of the bonding head unit 6000 with the bonding head fixture 6001 being used to process a workpiece 7020 is shown in FIG. 7. For ease and clarity of depiction, only a portion (i.e., below line 6050—see FIG. 6) of the bonding head unit 6000 is shown, with the understanding that the bonding head unit 6000 and the bonding head fixture 6001 are the same as illustrated in FIG. 6 and described above. Like structures are numbered alike.

As shown in FIG. 7, a vacuum is drawn at the workpiece contact surface 6002 via the vacuum channel 6014 to grip/hold onto the workpiece 7020 (see solid arrows 6042). As provided above, the present bonding head fixture designs can accommodate a variety of different workpiece configurations. For instance, in one embodiment, workpiece 7020 is a flexible substrate such as a thin film (e.g., having a thickness of less than or equal to 20 micrometers).

The workpiece 7020 is heated by heater 6034 through i) direct heating of the bonding head fixture 6001 (and this heat passes to the workpiece 7020 at the workpiece contact surface 6002) and ii) heating the fluid (e.g., a gas or a liquid) from the fluid source 6028 as it passes through the passage 6024 and into the recess 6004 (see dashed arrows 6040). As indicated by arrows 7030, the bonding head unit 6000/bonding head fixture 6001 are then used to bring the workpiece 7020 into contact with a workpiece 7032 while both force and heat (see above) are applied simultaneously. By way of example only, workpiece 7032 includes a die 7032a having contact pads 7032b.

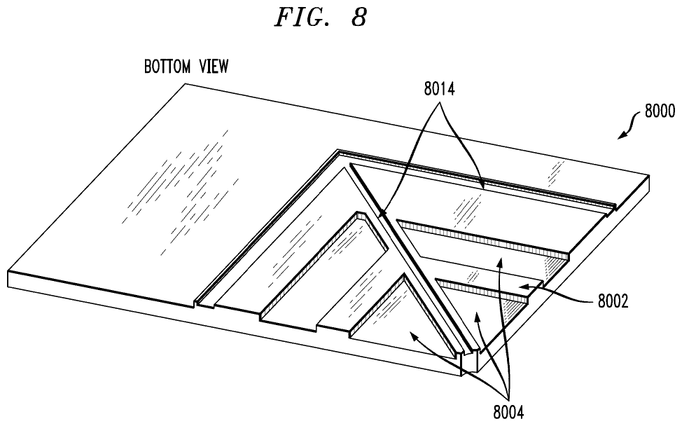

In the preceding examples, the bonding head fixture designs contain a single, centrally-located recess. However, embodiments are also contemplated herein where multiple recesses are present. See, for example, bonding head fixture 8000 shown in FIG. 8 (a three-dimensional quarter model). In order to illustrate unique elements of the present bond head fixture design at an interface with a workpiece, FIG. 8 provides a top-down view of a bottom of the bonding head fixture 8000.

As with the examples above, bonding head fixture 8000 has a workpiece contact surface 8002 that will make both direct physical and direct thermal contact with a given workpiece (not shown). Here, however, there are multiple recesses 8004 present in the workpiece contact surface 8002. Notably, where the recesses 8004 are present in the workpiece contact surface 8002, the bonding head fixture 8000 does not make direct physical and direct thermal contact with the workpiece. As in the preceding examples, a vacuum channel 8014 is present in the workpiece contact surface 8002. As shown in FIG. 8, the vacuum channel 8014 may pass in between the recesses 8004. By comparison with the preceding examples, the bonding head fixture 8000 does not contain (fluid flow) heat passages, but rather creates heat uniformity by redistributing the contact area making up the workpiece contact surface 8002.

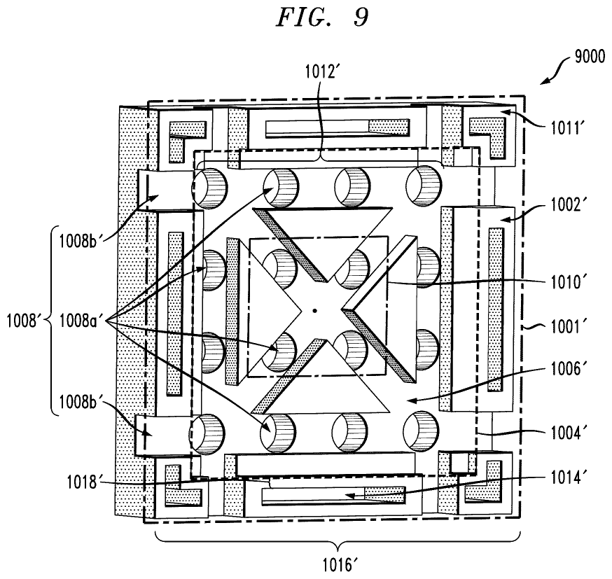

As described above, the fluid flow outlets can be located at the outer edge of the bonding head fixture in order to enhance lateral hot fluid flow. This approach can also be applied as a variant to the bonding head fixture design shown in FIG. 1 and described above. Namely, as shown with bonding head fixture 9000 in FIG. 9, all heat passages 1008′ over a recess 1004′ are flow inlets 1008a′ (i.e., FIG. 9 depicts a bottom of the bonding head fixture 9000), and fluid flow outlets 1008b′ are located at the outer edge of the bonding head fixture 9000.

As above, bonding head fixture 9000 has a workpiece contact surface 1002′ that makes both direct physical and direct thermal contact with a given workpiece 1001′ (the outline of which is shown with patterned dashes). Where the recess 1004′ is present in the workpiece contact surface 1002′, the bonding head fixture 9000 does not make direct physical and direct thermal contact with the workpiece. Namely, since surfaces of the bonding head fixture 9000 within the recess 1004′ are offset in from the workpiece contact surface 1002′, they will not make direct physical/thermal contact with the workpiece. See, for example, surface 1006′ of the bonding head fixture 9000 within the recess 1004′ which is set in from the workpiece contact surface 1002′.

In the same manner as above, the fluid flow inlets 1008a′ are connected to a heat source (not shown), and the fluid flow inlets 1008a′ and the fluid flow outlets 1008b′ will serve to direct a heated fluid (e.g., a gas or a liquid) into and out of the recess 1004′, respectively. The recess 1004′ serves to redistribute heat across the bonding head fixture 9000 in order to achieve heating uniformity. Namely, since there is no direct physical/thermal contact between the bonding head fixture 9000 and the workpiece within the recess 1004′, heat will not be allowed to pass directly through the bonding head fixture 9000 to the workpiece where the recess 1004′ is present (such as at a center 1010′ of the bonding head fixture 9000). At the same time, other areas of the bonding head fixture 9000 such as the workpiece contact surface 1002′ at corners 1011′ of the bonding head fixture 9000 directly contact the workpiece, allowing heat to pass directly through the bonding head fixture 9000 to the workpiece. This intentionally creates a secondary temperature non-uniformity to counter the initial center-to-corner variation described above.

Vacuum channels 1014′ are located in the workpiece contact surface 1002′ along an outer edge 1016′ of the bonding head fixture 9000. The vacuum channels 1014′ are connected to a vacuum source (not shown) and will serve to grip and hold onto the workpiece 1001′. Notably, in the instant example, the vacuum channels 1014′ are separate from (i.e., not connected to) the recess 1004′. Namely, a portion of the workpiece contact surface 1002′ (see, e.g., portion 1018′ of the workpiece contact surface 1002′) separates each of the vacuum channels 1014′ from the recess 1004′.

In one exemplary embodiment, the bonding head fixture 9000 is formed from a rigid material such as a metal like aluminum and/or copper. Standard machining process can be employed to pattern the above-described features such as the recess 1004′, the heat passages 1008′ (i.e., the fluid flow inlets 1008a′ and the fluid flow outlets 1008b′), the vacuum channels 1014′, etc. in the bonding head fixture 9000.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary bonding head fixture (e.g., bonding head fixture 1000, bonding head fixture 2000, bonding head fixture 4000, bonding head fixture 6001, bonding head fixture 8000, bonding head fixture 9000, etc.) includes: a workpiece contact surface (e.g., workpiece contact surface 1002, workpiece contact surface 2002, workpiece contact surface 4002, workpiece contact surface 6002, workpiece contact surface 8002, workpiece contact surface 1002′, etc.); at least one recess (e.g., recess 1004, recess 2004, recess 4004, recess 6004, recesses 8004, recess 1004′, etc.) in the workpiece contact surface; and heat passages (e.g., heat passages 1008, heat passages 2008, heat passages 4008, heat passages 6008, heat passages 1008′, etc.) leading into and out of the at least one recess.

In accordance with another aspect of the invention, an exemplary bonding head (e.g., bonding head 6060), includes: a bonding head fixture (e.g., bonding head fixture 1000, bonding head fixture 2000, bonding head fixture 4000, bonding head fixture 6001, bonding head fixture 8000, bonding head fixture 9000, etc.) having a workpiece contact surface (e.g., workpiece contact surface 1002, workpiece contact surface 2002, workpiece contact surface 4002, workpiece contact surface 6002, workpiece contact surface 8002, workpiece contact surface 1002′, etc.), at least one recess (e.g., recess 1004, recess 2004, recess 4004, recess 6004, recesses 8004, recess 1004′, etc.) in the workpiece contact surface, and heat passages (e.g., heat passages 1008, heat passages 2008, heat passages 4008, heat passages 6008, heat passages 1008′, etc.) leading into and out of the at least one recess; and a heat source (e.g., fluid source 6028 and the heater 6034) connected to at least one of the heat passages.

In accordance with yet another aspect of the invention, an exemplary method includes: gripping a workpiece (e.g., workpiece 1001, workpiece 3002, workpiece 5002, workpiece 6020, workpiece 7020, workpiece 1001′, etc.) with a bonding head fixture (e.g., bonding head fixture 1000, bonding head fixture 2000, bonding head fixture 4000, bonding head fixture 6001, bonding head fixture 8000, bonding head fixture 9000, etc.), the bonding head fixture having a workpiece contact surface (e.g., workpiece contact surface 1002, workpiece contact surface 2002, workpiece contact surface 4002, workpiece contact surface 6002, workpiece contact surface 8002, workpiece contact surface 1002′, etc.), at least one recess (e.g., recess 1004, recess 2004, recess 4004, recess 6004, recesses 8004, recess 1004′, etc.) in the workpiece contact surface, and heat passages (e.g., heat passages 1008, heat passages 2008, heat passages 4008, heat passages 6008, heat passages 1008′, etc.) leading into and out of the at least one recess, where the workpiece contact surface directly contacts the workpiece; and heating the workpiece by direct heating at the workpiece contact surface, and by providing heated fluid (e.g., a gas or a liquid) to the at least one recess via the heat passages.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed bonding techniques.

An integrated circuit in accordance with aspects of the present inventions can be employed in essentially any application and/or electronic system where one or more aspects of the disclosed techniques would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A bonding head fixture, comprising:
a workpiece contact surface;
at least one recess in the workpiece contact surface; and
heat passages leading into and out of the at least one recess.

2. The bonding head fixture of claim 1, wherein the heat passages comprise at least one fluid flow inlet and at least one fluid flow outlet.

3. The bonding head fixture of claim 2, wherein the at least one fluid flow inlet is located at a center of the bonding head fixture.

4. The bonding head fixture of claim 2, wherein the at least one fluid flow outlet is located along an inner edge of the bonding head fixture.

5. The bonding head fixture of claim 4, wherein the at least one fluid flow outlet comprises multiple fluid flow outlets arranged along the inner edge of the bonding head fixture.

6. The bonding head fixture of claim 2, wherein the at least one fluid flow outlet is located along an outer edge of the bonding head fixture.

7. The bonding head fixture of claim 6, wherein the at least one fluid flow outlet comprises multiple fluid flow outlets arranged along the outer edge of the bonding head fixture.

8. The bonding head fixture of claim 1, further comprising:
a vacuum channel in the workpiece contact surface along an outer edge of the bonding head fixture.

9. The bonding head fixture of claim 8, wherein the workpiece contact surface separates the vacuum channel from the at least one recess.

10. A bonding head, comprising:
a bonding head fixture having a workpiece contact surface, at least one recess in the workpiece contact surface, and heat passages leading into and out of the at least one recess; and
a heat source connected to at least one of the heat passages.

11. The bonding head of claim 10, wherein the heat passages comprise at least one fluid flow inlet and at least one fluid flow outlet, and wherein the heat source is connected to the at least one fluid flow inlet which is located at a center of the bonding head fixture.

12. The bonding head of claim 11, wherein the at least one fluid flow outlet is located along an inner edge of the bonding head fixture.

13. The bonding head of claim 11, wherein the at least one fluid flow outlet is located along an outer edge of the bonding head fixture.

14. The bonding head of claim 10, further comprising:
a vacuum channel in the workpiece contact surface along an outer edge of the bonding head fixture; and
a vacuum source connected to the vacuum channel.

15. The bonding head of claim 14, wherein the workpiece contact surface separates the vacuum channel from the at least one recess.

16. A method, comprising:
gripping a workpiece with a bonding head fixture, the bonding head fixture comprising a workpiece contact surface, at least one recess in the workpiece contact surface, and heat passages leading into and out of the at least one recess, wherein the workpiece contact surface directly contacts the workpiece; and
heating the workpiece by direct heating at the workpiece contact surface, and by providing a heated fluid to the at least one recess via the heat passages.

17. The method of claim 16, wherein the direct heating at the workpiece contact surface is provided by a heater that is in direct contact with the bonding head fixture.

18. The method of claim 17, wherein the providing of the heated fluid to the at least one recess, comprises:
passing fluid through a passage in the heater to generate the heated fluid.

19. The method of claim 16, wherein the bonding head fixture further comprises a vacuum channel in the workpiece contact surface, and wherein the gripping of the workpiece with the bonding head fixture further comprises:
drawing a vacuum at the workpiece contact surface via the vacuum channel to grip the workpiece.

20. The method of claim 19, wherein the workpiece contact surface separates the vacuum channel from the at least one recess.
